(19) United States
(12) Patent Application Publication
(10) Pub. No.: US 2024/0222569 A1
(43) Pub. Date: Jul. 4, 2024

(54) MICRO LIGHT-EMITTING CHIP STRUCTURE AND MICRO DISPLAY STRUCTURE

(71) Applicant: PlayNitride Display Co., Ltd., Zhunan Township (TW)

(72) Inventor: Yen-Yeh CHEN, Zhunan Township (TW)

(73) Assignee: PlayNitride Display Co., Ltd., Zhunan Township (TW)

(21) Appl. No.: 18/512,571

(22) Filed: Nov. 17, 2023

Related U.S. Application Data
(63) Continuation-in-part of application No. 18/147,474, filed on Dec. 28, 2022.

(51) Int. Cl. H01L 33/46; H01L 25/075

(52) U.S. Cl. CPC H01L 33/46; H01L 25/0753

(57) ABSTRACT

A micro light-emitting chip structure includes a first-type semiconductor layer, a light-emitting layer, and a second-type semiconductor layer having a peripheral surface and an end surface. The micro light-emitting chip structure includes a first insulating layer, a reflective layer, and a second insulating layer that cover at least the peripheral surface and the end surface. The reflective layer is disposed on the first insulating layer. The second insulating layer is disposed on the reflective layer. The micro light-emitting chip structure includes an electrode disposed on the end surface and connected to the second-type semiconductor layer. A gap is formed between the electrode and the reflective layer, so as to electrically insulate the electrode from the reflective layer.

### CROSS REFERENCE TO RELATED APPLICATIONS

This application is a Continuation-In-Part of pending U.S. patent application Ser. No. 18/147,474, filed Dec. 28, 2022, and entitled “MICRO LIGHT-EMITTING CHIP STRUCTURE AND MICRO DISPLAY STRUCTURE”, the entirety of which is incorporated by reference herein.

### BACKGROUND OF THE INVENTION

### Field of the Invention

The present invention relates to a micro light-emitting chip structure, and, in particular, to a micro light-emitting chip structure that includes a reflective layer covering at least the peripheral surface and the end surface of the second insulating layer, and a micro display structure using the same.

### Description of the Related Art

With the advancement of optoelectronic technology, the volume of many optoelectronic components is gradually becoming miniaturized. Compared with organic light-emitting diode (OLED) technology, micro light-emitting diodes (mLEDs/μLEDs) have the advantages of high efficiency, longer lifetime, and relatively stable materials that are not prone to being affected by the environment. Therefore, displays using micro light-emitting diodes fabricated in arrays are increasingly gaining attention in the market.

Recently, the technical trend in micro light-emitting diodes has been toward increasing the number of pixels per inch (PPI) in order to further improve the image resolution of the display. To achieve this objective, manufacturers have used a number of methods to reduce the pixel size of the micro light-emitting chip structure, one of which has been narrowing the process line width and adopting an array structure for a common electrode. However, as pixel sizes have decreased over time, the design and fabrication of micro light-emitting chip structures continue to face various challenges. For example, since the forward light-emitting area of a micro light-emitting chip structure is greatly reduced, it is necessary to form a reflective layer on the sidewall that can reflect light to improve light-emitting efficiency. When the pixel size is smaller, the difficulty of manufacturing this type of layer will also be significantly increased, and the micro light-emitting chip structure will be accompanied by a higher risk of failure. These problems need to be solved by improving the design of the micro slight-emitting chip structure.

### BRIEF SUMMARY OF THE INVENTION

According to some embodiments of the present disclosure, a micro light-emitting chip structure and a micro display structure using the same are provided. The micro light-emitting chip structure includes a reflective layer covering at least the peripheral surface and the end surface of the second insulating layer, which may reflect the light out of the desired direction to increase the amount of forward light output, thereby effectively improving the light-emitting efficiency of the micro light-emitting chip structure and the micro display structure using the same.

An embodiment of the present disclosure provides a micro light-emitting chip structure. The micro light-emitting chip structure includes a first-type semiconductor layer and a light-emitting layer disposed on the first-type semiconductor layer. The micro light-emitting chip structure also includes a second-type semiconductor layer disposed on one side of the light-emitting layer that is opposite the first-type semiconductor layer. The second-type semiconductor layer has a peripheral surface and an end surface that is connected to the peripheral surface. The micro light-emitting chip structure further includes a first insulating layer covering at least the peripheral surface and the end surface and a reflective layer disposed on the first insulating layer and covering at least the peripheral surface and the end surface. Moreover, the micro light-emitting chip structure includes a second insulating layer disposed on the reflective layer and covering at least the peripheral surface and the end surface and an electrode disposed on the end surface and connected to the second-type semiconductor layer. A gap is formed between the electrode and the reflective layer, so as to electrically insulate the electrode from the reflective layer.

In addition, an embodiment of the present disclosure provides a micro display structure. The micro display structure includes a display substrate and micro light-emitting chip structures arranged on the display substrate. The micro light-emitting chip structure includes a first-type semiconductor layer and a light-emitting layer disposed on the first-type semiconductor layer. The micro light-emitting chip structure also includes a second-type semiconductor layer disposed on one side of the light-emitting layer that is opposite the first-type semiconductor layer. The second-type semiconductor layer has a peripheral surface and an end surface that is connected to the peripheral surface. The micro light-emitting chip structure further includes a first insulating layer covering at least the peripheral surface and the end surface and a reflective layer disposed on the first insulating layer and covering at least the peripheral surface and the end surface. Moreover, the micro light-emitting chip structure includes a second insulating layer disposed on the reflective layer and covering at least the peripheral surface and the end surface and an electrode disposed on the end surface and connected to the second-type semiconductor layer. A gap is formed between the electrode and the reflective layer, so as to electrically insulate the electrode from the reflective layer. The first-type semiconductor layers of the micro light-emitting chip structures are connected with each other to form a common electrode structure.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a cross-sectional view illustrating a portion of the micro light-emitting chip structure according to some embodiments of the present disclosure.

FIG. 2A and FIG. 2B are cross-sectional views illustrating a portion of the micro light-emitting chip structure according to some other embodiments of the present disclosure.

FIG. 3A, FIG. 3B, and FIG. 3C are cross-sectional views illustrating a portion of the micro light-emitting chip structure according to some other embodiments of the present disclosure.

FIG. 4A is a cross-sectional view illustrating a portion of the micro display structure according to some embodiments of the present disclosure.

FIG. 4B is a top view of a portion of the micro display structure according to some embodiments of the present disclosure.

FIG. 5A is a cross-sectional view illustrating a portion of the micro display structure according to some other embodiments of the present disclosure.

FIG. 5B is a cross-sectional view illustrating the region E in FIG. 5A.

FIG. 6 is a cross-sectional view illustrating a portion of the micro display structure according to some other embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

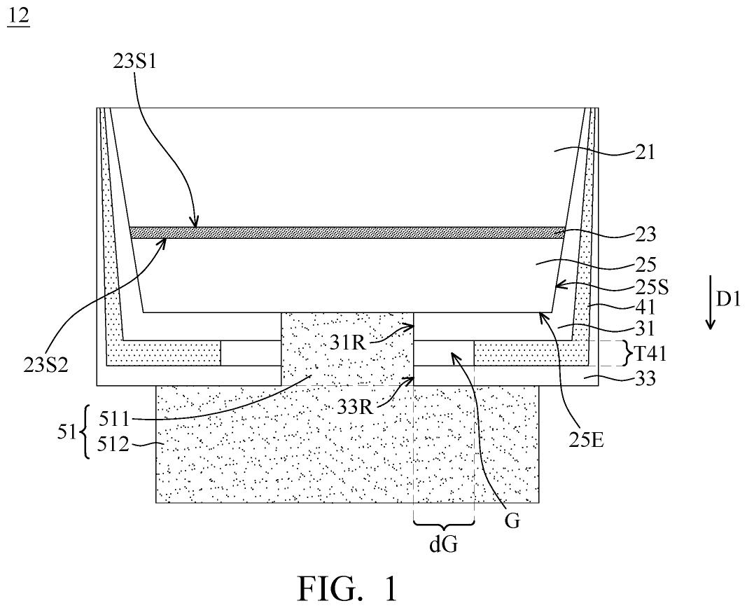

FIG. 1 is a cross-sectional view illustrating a portion of the micro light-emitting chip structure 12 according to some embodiments of the present disclosure. For example, the micro light-emitting chip structure 12 may be a micro light-emitting diode (micro LED). It should be noted that some components of the micro light-emitting chip structure 12 have been omitted in FIG. 1 for the sake of brevity.

Referring to FIG. 1, in some embodiments, the micro light-emitting chip structure 12 includes a first-type semiconductor layer 21. In some embodiments, the first-type semiconductor layer 21 includes an N-type semiconductor material. For example, the first-type semiconductor layer 21 may include a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the first-type semiconductor layer 21 may include dopants such as silicon (Si) or germanium (Ge), but the present disclosure is not limited thereto. Moreover, the first-type semiconductor layer 21 may be a single-layer or multi-layer structure.

Referring to FIG. 1, in some embodiments, the micro light-emitting chip structure 12 includes a light-emitting layer 23 disposed on the first-type semiconductor layer 21. The light-emitting layer 23 may include at least one undoped semiconductor layer or at least one low-doped semiconductor layer. For example, the light-emitting layer 23 may be a quantum well (QW) layer, which may include indium gallium nitride (InxGa1-xN) or gallium nitride (GaN), but the present disclosure is not limited thereto. Alternately, the light-emitting layer 23 may be a multiple quantum well (MQW) layer.

Lights emitted by the micro light-emitting chip structure 12 may be determined by the light-emitting layer 23. For example, the light-emitting layer 23 may emit red light, green light, or blue light, but the present disclosure is not limited thereto. The light-emitting layer 23 may also emit white light, cyan light, magenta light, yellow light, any other applicable color light, or a combination thereof.

Referring to FIG. 1, in some embodiments, the micro light-emitting chip structure 12 includes a second-type semiconductor layer 25 disposed on the side of the light-emitting layer 23 that is opposite the first-type semiconductor layer 21. For example, as shown in FIG. 1, the first-type semiconductor layer 21 is disposed on the first side 23S1 of the light-emitting layer 23, and the second-type semiconductor layer 25 is disposed on the second side 23S2 of the light-emitting layer 23. In some embodiments, the second-type semiconductor layer 25 includes a P-type semiconductor material. For example, the second-type semiconductor layer 25 may include a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the second-type semiconductor layer 25 may include dopants such as magnesium (Mg) or carbon (C), but the present disclosure is not limited thereto. Moreover, the second-type semiconductor layer 25 may be a single-layer or multi-layer structure.

As shown in FIG. 1, in some embodiments, the second-type semiconductor layer 25 has a peripheral surface 25S and an end surface 25E that is connected to the peripheral surface 25S. In the embodiment shown in FIG. 1, the end surface 25E of the second-type semiconductor layer 25 is a single flat surface, but the present disclosure is not limited thereto. In some other embodiments, the end surface 25E of the second-type semiconductor layer 25 is not limited to a single surface and may also be or includes an uneven surface.

The first-type semiconductor layer 21, the light-emitting layer 23, and the second-type semiconductor layer 25 may be formed by an epitaxial growth process. For example, the epitaxial growth process may include metal organic chemical vapor deposition (MOCVD), hydride vapor phase epitaxy (HVPE), molecular beam epitaxy (molecular beam epitaxy, MBE), any other applicable method, or a combination thereof.

Referring to FIG. 1, in some embodiments, the micro light-emitting chip structure 12 includes a first insulating layer 31 covering at least the peripheral surface 25S and the end surface 25E of the second-type semiconductor layer 25. For example, the first insulating layer 31 may include an inorganic insulating material, such as silicon oxide (SiO₂), silicon nitride (SiNₓ), aluminum oxide (Al₂O₃), titanium oxide (TiO₂), similar materials, or a combination thereof, but the present disclosure is not limited thereto.

The first insulating layer 31 may be formed by a deposition process and a patterning process. The deposition process may include chemical vapor deposition (CVD), atomic layer deposition (ALD), any other applicable method, or a combination thereof, but the present disclosure is not limited thereto. The patterning process may include forming a mask layer (not shown) on the aforementioned material, and then etching the portion of the aforementioned material covered by the mask layer (or the portion not covered by the mask layer), but the present disclosure is not limited thereto. The patterning process may also include a dry etching process or a wet etching process.

Referring to FIG. 1, in some embodiments, the micro light-emitting chip structure 12 includes a reflective layer 41 disposed on the first insulating layer 31 and covering at least the peripheral surface 25S and the end surface 25E of the second-type semiconductor layer 25. In some embodiments, the reflective layer 41 is a conductor. For example, the reflective layer 41 may include metal, such as titanium (Ti), aluminum (Al), silver (Ag), gold (Au), platinum (Pt), nickel (Ni), copper (Cu), the like, an alloy thereof, a multilayer stack thereof, or a combination thereof, but the present disclosure is not limited thereto. The reflective layer 41 may be formed by a deposition process and a patterning process. The examples of the deposition process and the patterning process are mentioned above and will not be repeated here.

Referring to FIG. 1, in some embodiments, the micro light-emitting chip structure 12 includes a second insulating layer 33 disposed on the reflective layer 41 and covering at least the peripheral surface 25S and the end surface 25E of the second-type semiconductor layer 25. The second insulating layer 33 may include the same or similar material as the first insulating layer 31 and may be formed by the same or similar process as the first insulating layer 31, which will not be repeated here, but the present disclosure is not limited thereto.

In the embodiment of the present disclosure, the first insulating layer 31, the reflective layer 41, and the second insulating layer 33 may form an insulator-metal-insulator (IMI) structure. As shown in FIG. 1, in some embodiments, the first insulating layer 31, the reflective layer 41, and the second insulating layer 33 conformally cover the peripheral surface 25S and a part of the end surface 25E. Moreover, as shown in FIG. 1, in some embodiments, the first insulating layer 31, the reflective layer 41, and the second insulating layer 33 extend toward the light-emitting layer 23 and the first-type semiconductor layer 21 along the peripheral surface 25S and cover the light-emitting layer 23 and a part of the first-type type semiconductor layer 21.

Referring to FIG. 1, in some embodiments, the micro light-emitting chip structure 12 includes an electrode 51 disposed on the end surface 25E of the second-type semiconductor layer 25 and connected to the second-type semiconductor layer 25. That is, the electrode 51 is in direct contact to the second-type semiconductor layer 25. Moreover, the electrode 51 is adjacent to the reflective layer 41 on the end surface 25E of the second-type semiconductor layer 25. The electrode 51 may include a conductive material, such as metal, metal silicide, the like, or a combination thereof. For example, the metal may be gold (Au), nickel (Ni), platinum (Pt), palladium (Pd), iridium (Ir), titanium (Ti), chromium (Cr), tungsten (W), aluminum (Al), copper (Cu), the like, an alloy thereof, or a combination thereof, but the present disclosure is not limited thereto.

As shown in FIG. 1, in some embodiments, the electrode 51 and the reflective layer 41 completely cover the peripheral surface 25S and the end surface 25E of the second-type semiconductor layer 25. In other words, the orthogonal projections of the electrode 51 and the reflective layer 41 on a reference plane parallel to the light-emitting layer 23 completely covers the orthogonal projection of the first-type semiconductor layer 21, the light-emitting layer 23, or the second-type semiconductor layer 25 on the reference plane.

As shown in FIG. 1, in some embodiments, a gap G is formed between the electrode 51 and the reflective layer 41, so as to electrically insulate the electrode from the reflective layer. In other words, the reflective layer 41 is retracted compared to the first insulating layer 31 and the second insulating layer 33, thereby forming a gap G. Here, the gap G may prevent the contact between the electrode 51 and the reflective layer 41 from causing a short circuit.

In some other embodiments, the gap G is an air gap. In other word, there are void between the electrode 51 and the reflective layer 41, so as to increase the resistivity. In some other embodiments, the ratio of the shortest distance dG between the electrode 51 and the reflective layer 41 in the gap G to the thickness T41 of the reflective layer 41 in the thickness direction D1 that is perpendicular to the end surface 25E is greater than or equal to about 1, so as to ensure that the electrode 51 is electrically insulated from the reflective layer 41.

Moreover, in some embodiments, the ratio of the shortest distance dG between the electrode 51 and the reflective layer 41 in the gap G to the thickness T41 of the reflective layer 41 in the thickness direction D1 that is perpendicular to the end surface 25E is less than about 7, so as to maintain the efficiency of the reflective layer 41 in reflecting light.

The ratio of the shortest distance dG between the electrode 51 and the reflective layer 41 in the gap G to the thickness T41 of the reflective layer 41 in the thickness direction D1 that is perpendicular to the end surface 25E may be about 2 and about 5. For example, the shortest distance dG between the electrode 51 and the reflective layer 41 in the gap G may be in the range from about 0.1 μm to about 5 μm (e.g., 0.5 μm), and the thickness T41 of the reflective layer 41 in the thickness direction D1 may be in the range from about 0.1 μm to about 1 μm (e.g., 0.2 μm), but the present disclosure is not limited thereto.

As shown in FIG. 1, the peripheral surface 25S of the second-type semiconductor layer 25 is an inclined surface, and the cross-sectional width of the second-type semiconductor layer 25 gradually narrows in the direction that is parallel to the light-emitting layer 23 (i.e., direction D1 in FIG. 1) toward the electrode 51. In this embodiment, since the first insulating layer 31, the reflective layer 41, and the second insulating layer 33 conformally cover the peripheral surface 25S and a part of the end surface 25E of the second-type semiconductor layer 25 (that is, the base surface covered by the insulation-metal- insulation conformal structure (i.e., the peripheral surface 25S of the second-type semiconductor layer 25) is not a steep surface), which may ensure that the reflective layer 41 is uniformly formed on the peripheral surface 25S of the second-type semiconductor layer 25 during the deposition process.

Moreover, the gradual-narrowing cross-sectional width of the second-type semiconductor layer 25 may reduce the incident angle of most incident light on the first insulating layer 31 from the light-emitting layer 23, so that the light is easily transmitted to the reflective layer 41 for reflection, and the probability of total reflection along the surface of the first insulating layer 31 is reduced, thereby effectively improving the overall light-emitting efficiency of the micro light-emitting chip structure.

In some embodiments, the ratio of the area of the orthogonal projection of the reflective layer 41 to the area of the orthogonal projection of the first-type semiconductor layer 21 (or the light-emitting layer 23 or the second-type semiconductor layer 25) on a reference plane parallel to the light-emitting layer 23 is between about 0.6 and about 0.85, so that the reflective layer 41 may provide adequate reflection.

As shown in FIG. 1, in some embodiments, the electrode 51 includes (or is divided into) an electrode pillar 511 and an electrode pad 512. The electrode pillar 511 is connected to the second-type semiconductor layer 25, and the electrode pad 512 is connected to the electrode pillar 511 and disposed on the second insulating layer 33. In more detail, the electrode pillar 511 may be in direct contact with the second-type semiconductor layer 25, and the electrode pad 512 may extend from the electrode pillar 511 to a surface of the second insulating layer 33, but the present disclosure is not limited thereto.

In some embodiments, the orthogonal projection of the electrode pad 512 covers the orthogonal projection of the gap G on a reference plane parallel to the light-emitting layer 23, so as to avoid light leakage. The electrode pad 512 may be made of metal material and may be matched with the reflective layer 41 to reflect the light emitted by the light-emitting layer 23 as much as possible and then emit it through the light-emitting surface.

Moreover, as shown in FIG. 1, in some embodiments, the first insulating layer 31 and the second insulating layer 33 each have an annular contact surface with the electrode 51 (e.g., the electrode pillar 511) on the end surface 25E of the second-type semiconductor layer 25. The annular contact surface 31R of the first insulating layer 31 and the annular contact surface 33R of the second insulating layer 33 are aligned with each other in the thickness direction of the end surface 25E of the second-type semiconductor layer 25 (i.e., direction D1 in FIG. 1).

Compared to a reflective layer using a multi-layer dielectric coating (e.g., distributed Bragg reflector (DBR)), within the IMI structure, constructing a reflective layer using the metallic electrode 51 offers superior conformability when covering the epitaxial structure (i.e., the second-type semiconductor layer 23, the light-emitting layer 23, and the first-type semiconductor 21). This improved conformability may prevent the formation of cracks, allowing for a more comprehensive encapsulation of the epitaxial structure (on both the surface connected to the electrode 51 and the sidewalls). A more complete encapsulation of the epitaxial structure contributes to maintaining enhanced light reflection efficacy.

The lateral surface of the epitaxial structure covered by the IMI structure is not steep, ensuring that the reflective layer (metallic electrode 51) uniformly forms on the side surface of the epitaxial structure during the deposition process.

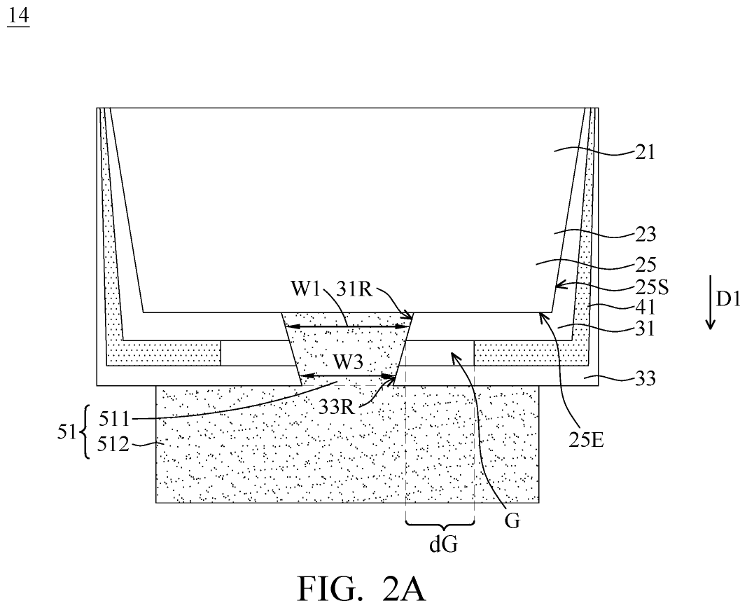

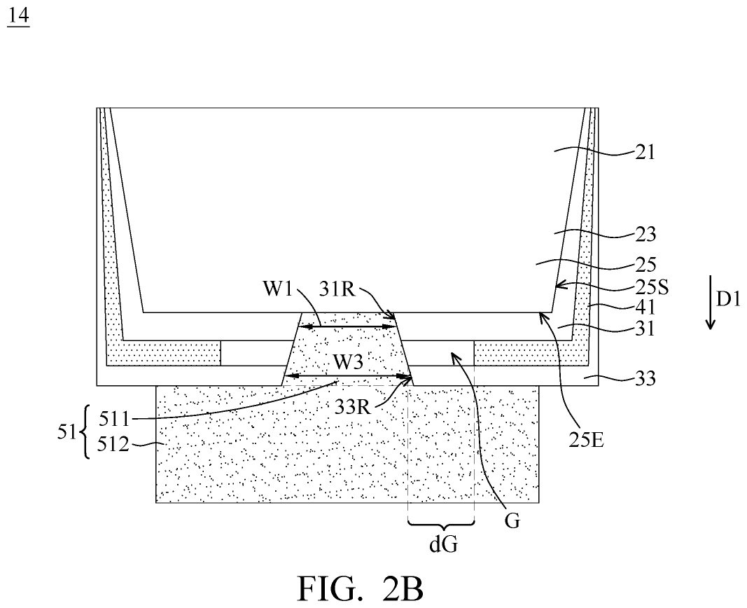

FIG. 2A and FIG. 2B are cross-sectional views illustrating a portion of the micro light-emitting chip structure 14 according to some other embodiments of the present disclosure. Similarly, some components of the micro light-emitting chip structure 14 have been omitted in FIG. 2A and FIG. 2B for the sake of brevity.

Referring to FIG. 2A and FIG. 2B, in some embodiments, in a cross-sectional view, the electrode pillar 511 has a variable width. In these embodiments, the first insulating layer 31 and the second insulating layer 33 each have an annular contact surface with the electrode on the end surface, and the annular contact surface 31R of the first insulating layer 31 has an offset relative to the annular contact surface 33R of the second insulating layer 33R in the thickness direction of the end surface (i.e., direction D1 in FIG. 2A and FIG. 2B).

As shown in the cross-sectional of FIG. 2A, in this embodiment, the electrode pillar 511 of the micro light-emitting chip structure 14 is formed into a trapezoid with a wide top and a narrow bottom. That is, the width W1 of the electrode pillar 511 that corresponds to (the annular contact surface 31R of) the first insulating layer 31 may be greater than the width W3 of the electrode pillar 511 that corresponds to (the annular contact surface 33R of) the second insulating layer 33. Here, the width W1 is defined as an average width of the electrode pillar 511 that corresponds to the first insulating layer 31, and the width W2 is defined as an average width of the electrode pillar 511 that corresponds to the second insulating layer 33.

As shown in FIG. 2A, the shortest distance dG between the electrode 51 and the reflective layer 41 in the gap G is the distance between one end of the electrode pillar 511 and the reflective layer 41 at the top of the gap G.

As shown in the cross-sectional of FIG. 2B, in this embodiment, the electrode pillar 511 of the micro light-emitting chip structure 14 is formed into a trapezoid with a narrow top and a wide bottom. That is, the width W1 of the electrode pillar 511 that corresponds to (the annular contact surface 31R of) the first insulating layer 31 may be less than the width W3 of the electrode pillar 511 that corresponds to (the annular contact surface 33R of) the second insulating layer 33. Similarly, the width W1 is defined as an average width of the electrode pillar 511 that corresponds to the first insulating layer 31, and the width W2 is defined as an average width of the electrode pillar 511 that corresponds to the second insulating layer 33.

As shown in FIG. 2B, the shortest distance dG between the electrode 51 and the reflective layer 41 in the gap G is the distance between one end of the electrode pillar 511 and the reflective layer 41 at the bottom of the gap G.

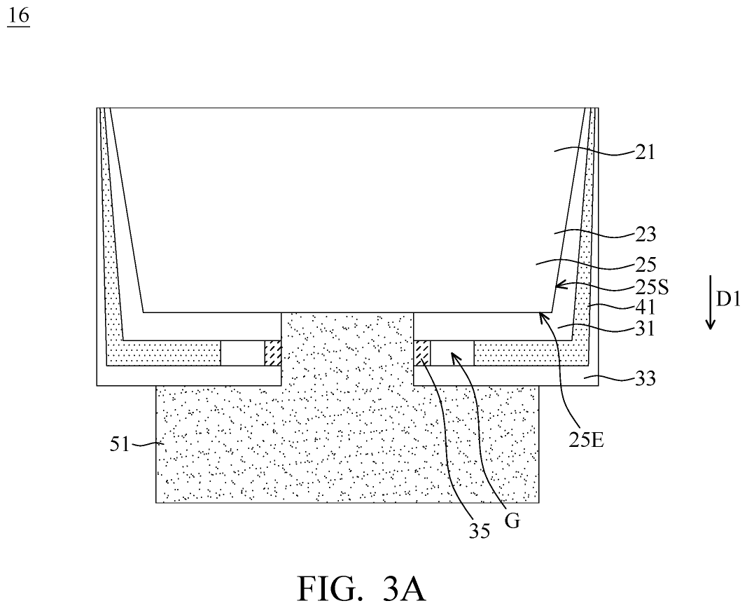

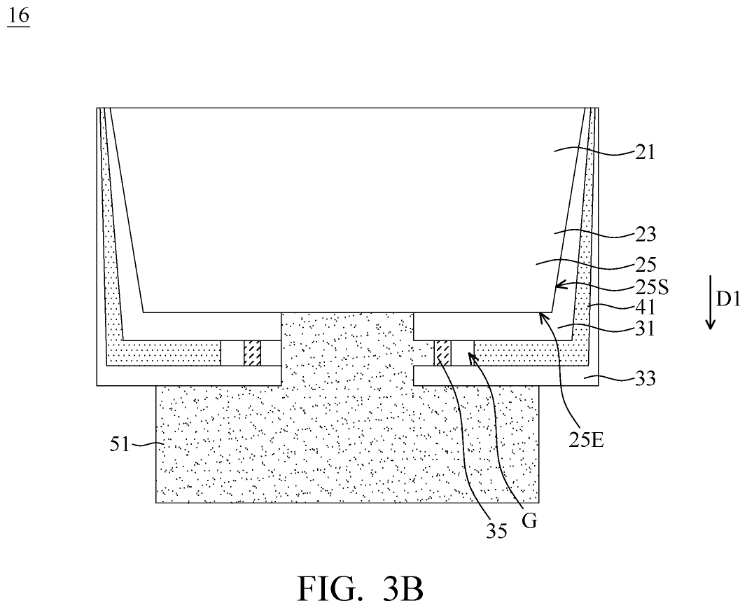

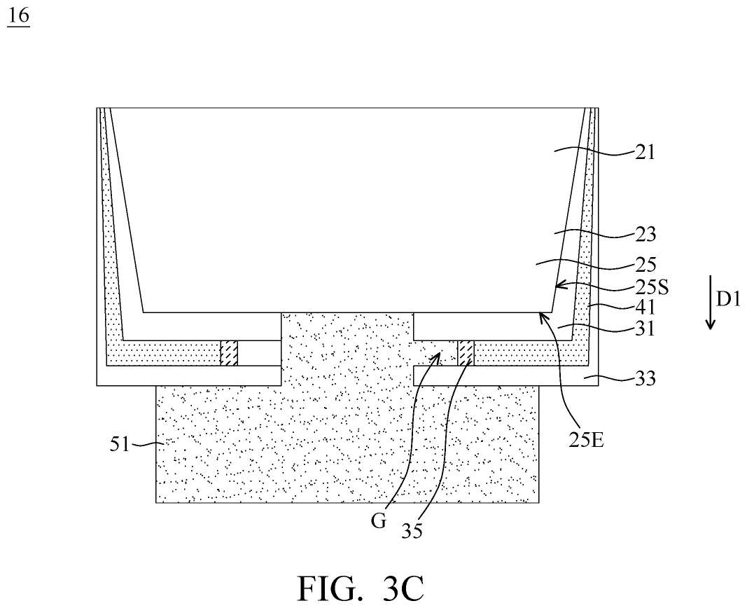

FIG. 3A, FIG. 3B, and FIG. 3C are cross-sectional views illustrating a portion of the micro light-emitting chip structure 16 according to some other embodiments of the present disclosure. Similarly, some components of the micro light-emitting chip structure 16 have been omitted in FIG. 3A, FIG. 3B, and FIG. 3C for the sake of brevity.

Referring to FIG. 3A, FIG. 3B, and FIG. 3C, in some embodiments, the micro light-emitting chip structure 16 further includes a dielectric structure 35 disposed in the gap. For example, the dielectric structure 35 may include the same or similar material as the first insulating layer 31 or the second insulating layer 33. In this example, the first insulating layer 31, the second insulating layer 33, and the dielectric structure 35 may be regarded as the same component, but the present disclosure is not limited thereto. In other example, the dielectric structure 35 may be made of different material than the first insulating layer 31 and the second insulating layer 33 (e.g., the dielectric structure 35 may include organic materials, structural photoresist materials, any other similar material, or a combination thereof). In some embodiments, the dielectric structure 35 is a ring structure formed between the first insulating layer 31 and the second insulating layer 33.

In these embodiments, the dielectric structure 35 may further prevent the diffusion or deposition of the process gas of electrode 51 into the gap G in the process of making electrode 51, so as to avoid the occurrence of short circuits.

As shown in FIG. 3A, the dielectric structure 35 is in direct contact with the electrode. For example, the dielectric structure 35 may be formed on the edge of the gap G closest to the electrode 51. Moreover, in the embodiment shown in FIG. 3A, the dielectric structure 35 is separated from the reflective layer 41.

As shown in FIG. 3B, the dielectric structure 35 is separated from the reflective layer 41. For example, the dielectric structure 35 may be formed inside the gap G. Moreover, in the embodiment shown in FIG. 3B, a portion of the electrode 51 (i.e., electrode pillar 511) may extend into the gap G, but may be blocked by the dielectric structure 35, so as to be electrically isolated from the reflective layer 41, such as the right side shown in FIG. 3B, but the preset disclosure is not limited thereto. In some embodiments, the dielectric structure 35 is separated from both the electrode 51 and the reflective layer 41, such as the left side shown in FIG. 3B.

As shown in FIG. 3C, the dielectric structure 35 is in direct contact with the reflective layer 41. For example, the dielectric structure 35 may be formed on the edge of the gap G closest to the reflective layer 41. Moreover, in the embodiment shown in FIG. 3C, a portion of the electrode 51 (i.e., electrode pillar 511) may extend into the gap G to fill the gap G, but may be separated from the reflective layer 41 by the dielectric structure 35, such as the right side shown in FIG. 3C, but the preset disclosure is not limited thereto. In some embodiments, the dielectric structure 35 is separated from both the electrode 51, such as the left side shown in FIG. 3C.

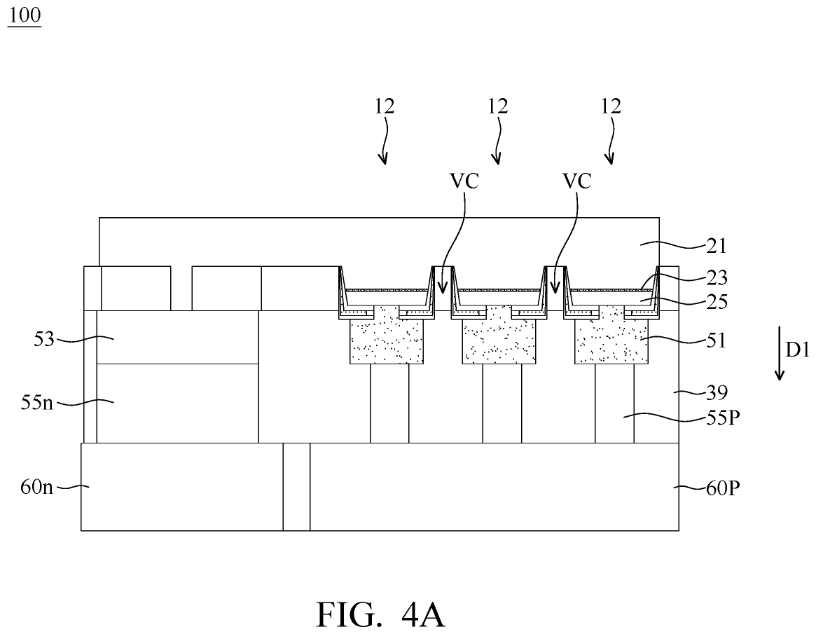

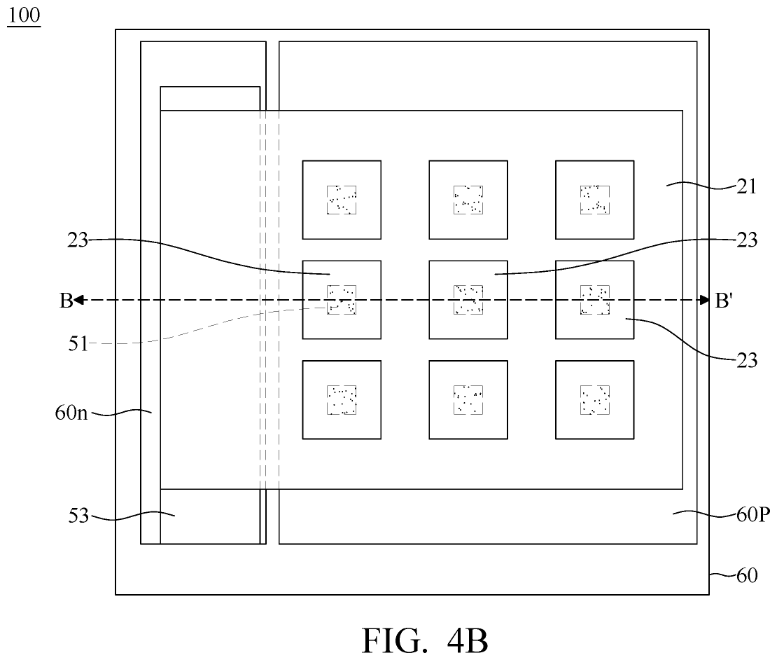

FIG. 4A is a cross-sectional view illustrating a portion of the micro display structure 100 according to some embodiments of the present disclosure. FIG. 4B is a top view of a portion of the micro display structure 100 according to some embodiments of the present disclosure. For example, FIG. 4A may be, for example, a cross-sectional view taken along line B-B′ in FIG. 4B, but the present disclosure is not limited thereto. Similarly, some components of the micro display structure 100 have been omitted in FIG. 4A and FIG. 4B for the sake of brevity. Moreover, what is shown in FIG. 4B is only a part of the array structure of the micro display structure 100. For convenience of description, the boundary lines of related components are not drawn according to the actual display configuration.

Referring to FIG. 4A and FIG. 4B, the micro display structure 100 includes a display substrate 60. The display substrate 60 may include an elementary semiconductor (e.g., silicon or germanium), a compound semiconductor (e.g., silicon carbide (SiC), gallium arsenic (GaAs), indium arsenide (InAs), or indium phosphide (InP)), an alloy semiconductor (e.g., silicon germanium (SiGe), silicon germanium carbide (SiGeC), gallium arsenic phosphide (GaAsP), or gallium indium phosphide (GaInP)), any other applicable semiconductor, or a combination thereof. Referring to FIG. 4B, the micro light-emitting chip structures 12 (e.g., the light-emitting layers 23 and the electrodes 51) are arranged on the display substrate 60 in an array and electrically connected to the display substrate 60.

The display substrate 60 may have an integrated circuit (IC) composed of various circuit layers. As shown in FIG. 4A, the circuit layers may include a p-pole 60p and an n-pole 60n. The micro light-emitting chip structures 12 may be electrically connected to the p-pole 60p of the circuit layer through their respective electrodes 51 (e.g., the electrodes 51 are connected to the conductive channel 55p), thereby independently controlling the micro light-emitting chip structures 12.

As shown in FIG. 4A, in some embodiments, the micro display structure 100 further includes an underfill layer 39 for stabilizing the overall structure of the micro display structure 100 and preventing moisture from entering the micro display structure 100. For example, the underfill layer 39 may include the same or similar material as the first insulating layer 31 and the second insulating layer 33, but the present disclosure is not limited thereto.

As shown in FIG. 4A and FIG. 4B, in some embodiments, the first-type semiconductor layers 21 of the micro light-emitting chip structures 12 are connected with each other to form a common electrode structure. The common electrode structure may be electrically connected to the n-pole 60n of the circuit layer through the conductive channel 55n (e.g., the first-type semiconductor layer 21 is connected to the pad 53, and the pad 53 is connected to the conductive channel 55n), but the present disclosure is not limited thereto. The common electrode structure may reduce the layout of circuits, improve the light-emitting efficiency of micro light-emitting chip structures 12, and increase the brightness of the micro display structure 100.

Moreover, as shown in FIG. 4A, the epitaxial structure (i.e., the first-type semiconductor layer 21, the light-emitting layer 23, and the second-type semiconductor layer) at the connected region of two adjacent micro light-emitting chip structures 12 is not encapsulated by the IMI structure (i.e., spacing VC), so the cross-talk light may pass through this region, exit the epitaxial structure, and will not propagate to the neighboring micro light-emitting chip structures 12.

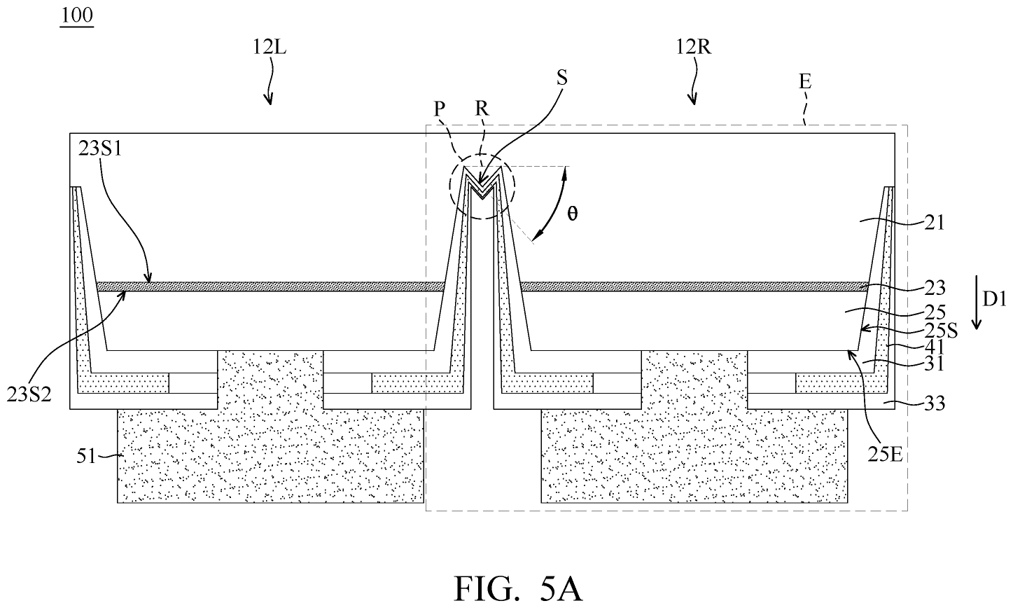

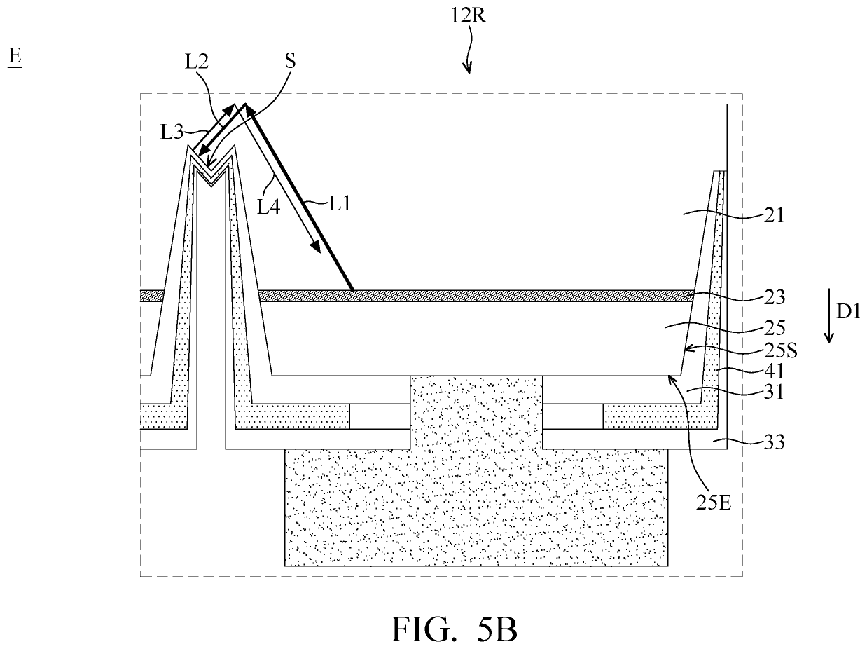

FIG. 5A is a cross-sectional view illustrating a portion of the micro display structure 100 according to some other embodiments of the present disclosure. FIG. 5B is a cross-sectional view illustrating the region E in FIG. 5A. Similarly, some components of the micro display structure 102 have been omitted in FIG. 5 for the sake of brevity.

As shown in FIG. 5A, in some embodiments, the first insulating layer 31, the reflective layer 41, and the second insulating layer 33 form a protruding structure P at a junction of two adjacent micro light-emitting chip structures 12L and 12R, and the protruding structure P has at least one inclined surface S. When light emitted from one of the micro light-emitting chip structures 12L and 12R reflects on the light-emitting surface of the adjacent region and is about to propagate towards another one of the micro light-emitting chip structures 12L and 12R, it is reflected by the inclined surface S of the protruding structure P and bounces back in the direction of the original micro light-emitting chip structures 12L or 12R.

In other words, in some embodiments, the protruding structure P reflects the light from the farther one of the micro light-emitting chip structures 12L and 12R. This helps to mitigate the optical cross-talk issues between different micro light-emitting chip structures 12L and 12R. In some embodiments, an included angle θ between the inclined surface S and the reference plane R parallel to the light-emitting layer 23 is between about 15° and about 75° (e.g., 15°, 30°, 45°, 60°, or 75°.

In this embodiment, the protruding structure P is formed into an M-shaped structure. For example, as shown in FIG. 5B, light emitted from the light-emitting layer 23 of the micro light-emitting chip structure 12R will proceed along the optical path L1, the optical path L2, the optical path L3 and the optical path L4 in sequence. In more detail, when light emitted from the micro light-emitting chip structure 12R reflects on the light-emitting surface and is about to propagate towards the micro light-emitting chip structures 12L, it is reflected by the farther inclined surface S of the protruding structure P (i.e., the inclined surface S closer to the micro light-emitting chip structure 12L) and bounces back in the direction of the micro light-emitting chip structure 12R. 12L and 12R.

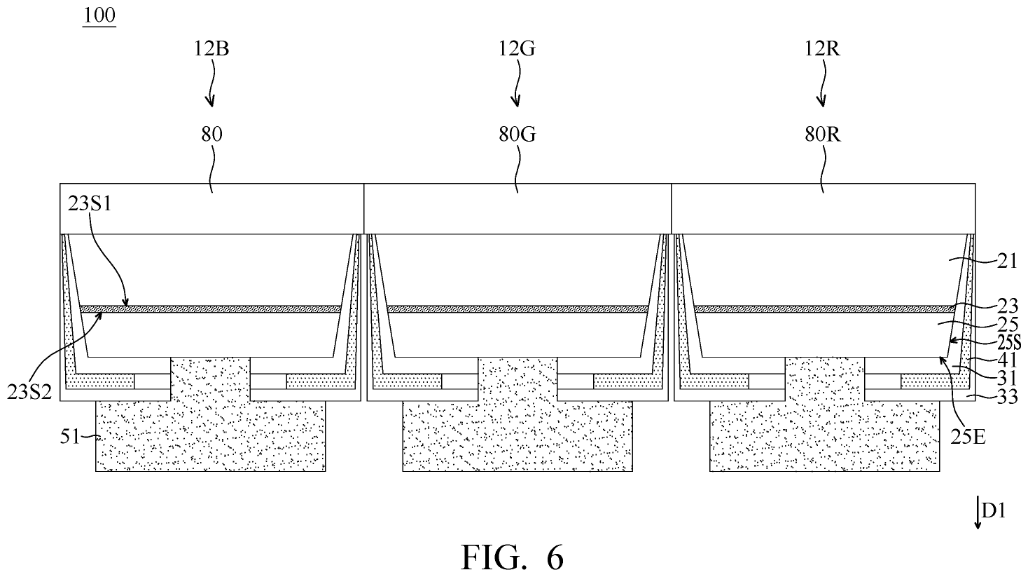

FIG. 6 is a cross-sectional view illustrating a portion of the micro display structure 100 according to some other embodiments of the present disclosure. Similarly, some components of the micro display structure 100 have been omitted in FIG. 6 for the sake of brevity.

Referring to FIG. 6, in some embodiments, each micro light-emitting chip structure 12 emits light of the same color. In other words, the light-emitting layer 23 of each micro light-emitting chip structure 12 emits light of the same color, such as blue. In this embodiment, the micro display structure 100 further includes multiple color conversion structures 80G, 80R arranged on some micro light-emitting chip structures 12, and the color conversion structures 80G, 80R convert the light emitted by the micro light-emitting chip structure 12 into light of different colors.

For example, the color conversion structure 80G may include green phosphors or green quantum dots (QDs) to convert the blue light emitted by the micro light-emitting chip structure 12 into green light; the color conversion structure 80R may include red phosphor or red quantum dots to convert the blue light emitted by the micro light-emitting chip structure 12 into red light, but the present disclosure is not limited thereto. In some other embodiments, the micro-light-emitting chip structures 12 emit lights of different colors.

As noted above, the micro light-emitting chip structure according to the embodiments of the present disclosure includes a reflective layer covering at least the peripheral surface and the end surface of the second insulating layer, which may reflect the light out of the desired direction to increase the amount of forward light output, thereby effectively improving the light-emitting efficiency of the micro light-emitting chip structure and the micro display structure using the same.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A micro light-emitting chip structure, comprising:
a first-type semiconductor layer;
a light-emitting layer disposed on the first-type semiconductor layer;
a second-type semiconductor layer disposed on one side of the light-emitting layer that is opposite the first-type semiconductor layer, wherein the second-type semiconductor layer has a peripheral surface and an end surface that is connected to the peripheral surface;
a first insulating layer covering at least the peripheral surface and the end surface;
a reflective layer disposed on the first insulating layer and covering at least the peripheral surface and the end surface;
a second insulating layer disposed on the reflective layer and covering at least the peripheral surface and the end surface; and
an electrode disposed on the end surface and connected to the second-type semiconductor layer, wherein a gap is formed between the electrode and the reflective layer, so as to electrically insulate the electrode from the reflective layer.

2. The micro light-emitting chip structure as claimed in claim 1, wherein the gap is an air gap.

3. The micro light-emitting chip structure as claimed in claim 1, wherein the ratio of a shortest distance between the electrode and the reflective layer in the gap to a thickness of the reflective layer in a thickness direction perpendicular to the end surface is greater than or equal to 1.

4. The micro light-emitting chip structure as claimed in claim 3, wherein the ratio of the shortest distance between the electrode and the reflective layer in the gap to the thickness of the reflective layer in the thickness direction perpendicular to the end surface is less than 7.

5. The micro light-emitting chip structure as claimed in claim 1, wherein the ratio of an area of an orthogonal projection of the reflective layer to an area of an orthogonal projection of the first-type semiconductor layer on a reference plane parallel to the light-emitting layer is between 0.6 and 0.85.

6. The micro light-emitting chip structure as claimed in claim 1, wherein the electrode comprises:
an electrode pillar connected to the second-type semiconductor layer; and
an electrode pad connected to the electrode pillar and disposed on the second insulating layer.

7. The micro light-emitting chip structure as claimed in claim 6, wherein an orthogonal projection of the electrode pad covers an orthogonal projection of the gap on a reference plane parallel to the light-emitting layer.

8. The micro light-emitting chip structure as claimed in claim 6, wherein in a cross-sectional view, the electrode pillar has a variable width.

9. The micro light-emitting chip structure as claimed in claim 1, wherein the first insulating layer and the second insulating layer each have an annular contact surface with the electrode on the end surface, and the annular contact surface of the first insulating layer has an offset relative to the annular contact surface of the second insulating layer in a thickness direction of the end surface.

10. The micro light-emitting chip structure as claimed in claim 1, further comprising:
a dielectric structure disposed in the gap.

11. The micro light-emitting chip structure as claimed in claim 10, wherein the dielectric structure is in direct contact with the electrode.

12. The micro light-emitting chip structure as claimed in claim 10, wherein the dielectric structure is separated from the reflective layer.

13. The micro light-emitting chip structure as claimed in claim 10, wherein the dielectric structure is in direct contact with the reflective layer.

14. The micro light-emitting chip structure as claimed in claim 1, wherein the peripheral surface is an inclined surface, and the first insulating layer, the reflective layer, and the second insulating layer conformally cover the peripheral surface and a part of the end surface.

15. A micro display structure, comprising:
a display substrate;
micro light-emitting chip structures arranged on the display substrate, wherein each of the micro light-emitting chip structures comprises:
a first-type semiconductor layer;
a light-emitting layer disposed on the first-type semiconductor layer;
a second-type semiconductor layer disposed on one side of the light-emitting layer that is opposite the first-type semiconductor layer, wherein the second-type semiconductor layer has a peripheral surface and an end surface that is connected to the peripheral surface;
a first insulating layer covering at least the peripheral surface and the end surface;
a reflective layer disposed on the first insulating layer and covering at least the peripheral surface and the end surface;
a second insulating layer disposed on the reflective layer and covering at least the peripheral surface and the end surface; and
an electrode disposed on the end surface and connected to the second-type semiconductor layer, wherein a gap is formed between the electrode and the reflective layer, so as to electrically insulate the electrode from the reflective layer,
wherein the first-type semiconductor layers of the micro light-emitting chip structures are connected with each other to form a common electrode structure.

16. The micro display structure as claimed in claim 15, wherein the first insulating layers, the reflective layers, and the second insulating layers of the micro light-emitting chip structures are connected with each other.

17. The micro display structure as claimed in claim 16, wherein the first insulating layers, the reflective layers, and the second insulating layers form a protruding structure at a junction of adjacent two of the micro light-emitting chip structures, and the protruding structure has at least one inclined surface.

18. The micro display structure as claimed in claim 17, wherein an included angle between the inclined surface and a reference plane parallel to the light-emitting layer is between 15° and 75°.

19. The micro display structure as claimed in claim 17, wherein the protruding structure reflects a light from a farther one of the micro light-emitting chip structures.

20. The micro display structure as claimed in claim 15, wherein the micro-light-emitting chip structures emit light of the same color, and the micro display structure further comprises:
color conversion structures disposed on some of the micro light-emitting chip structures, wherein the color conversion structures convert the light emitted by the micro light-emitting chip structures into light of different colors.
